(19) United States
(12) Patent Application Publication
(10) Pub. No.: US 2002/0078895 A1
(43) Pub. Date: Jun. 27, 2002

(54) Plasma treatment apparatus

(75) Inventor: Youngduk Yoon, Tokyo (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: THE FURUKAWA ELECTRIC CO., LTD., Chiyoda-ku (JP)

(21) Appl. No.: 09/924,487

(22) Filed: Aug. 9, 2001

(30) Foreign Application Priority Data
Dec. 27, 2000 (JP) 2000-399424

(51) Int. Cl. C23C 16/00; C23F 1/02

(52) U.S. Cl. 118/729; 156/345.54

(57) ABSTRACT

The plasma treatment apparatus includes the plasma chamber and the film forming chamber in which plasma flow is generated. The target sputters target particles in the plasma flow. The substrate onto which a thin film is to be formed in held by the stage. The target particles are deposited on the substrate thereby forming the thin film. The arm moves the stage in a direction perpendicular to the plasma flow in such a manner that the plasma flow is always irradiated on the entire surface of the substrate.

### FIELD OF THE INVENTION

The present invention relates to a plasma treatment apparatus for performing plasma treatment on a substrate such as a semiconductor substrate. Plasma treatment means sputtering, etching, or milling.

### BACKGROUND OF THE INVENTION

Conventionally, substrates such as semiconductor substrates have been treated by using various types of plasma treatment such as sputtering, etching, or milling in association with miniaturization of electronic components.

FIG. 5 is a cross-sectional view showing a basic structure of a conventional sputtering film forming apparatus. This sputtering film forming apparatus includes a microwave power supply 21, a plasma chamber 22, a magnetic coil 23, a coil power supply 24, a target 25, a film forming chamber 26, a sample stand 29, a gas introduction system 32, a sputtering power supply 34, and an evacuation system 35.

The plasma chamber 22 is connected to the film forming chamber 26. The microwave power supply 21 is connected to the plasma chamber 22 and supplies microwaves to the plasma chamber 22. The magnetic coil 23 is disposed around the plasma chamber 22. The coil power supply 24 is connected to the magnetic coil 23 and supplies power to the magnetic coil 23.

The evacuation system 35 evacuates the plasma chamber 22 and the film forming chamber 26 to a high vacuum. The gas introduction system 32 introduces gas to the plasma chamber 22 and the film forming chamber 26. The target 25 having a film forming material is disposed at a joint between the plasma chamber 22 and the film forming chamber 26, and is connected to the sputtering power supply 34. The sample stand 29 is disposed in the film forming chamber 26 to hold a substrate 28.

The conventional sputtering film forming apparatus forms a film in a manner as explained below. The plasma chamber 22 and the film forming chamber 26 are evacuated to a high vacuum by the evacuation system 35, and gas is introduced to a desired pressure by the gas introduction system 32. Microwave power is supplied from the microwave power supply 21 to the plasma chamber 22, in which a magnetic field is formed by the magnetic coil 23. The introduced gas is subjected to electron cyclotron resonance (ECR) in the plasma chamber 22 to form plasma, which becomes a plasma flow 27 flowing from the plasma chamber 22 to the film forming chamber 26.

The sputtering power supply 34 supplies power to the target 25 disposed so as to surround the plasma flow 27, and target particles are scattered through sputtering. The sputtered target particles are deposited on the substrate 28 fixed to the sample stand 29 to form a thin film.

FIG. 6 shows a distribution of the thickness of an aluminum oxide thin film on the substrate 28 formed by the conventional sputtering film forming apparatus. In FIG. 6, the film thickness at the central part of the substrate is about 140 nm and the film thickness in its peripheral part is about 100 nm.

However, in association with progress in miniaturization of the electronic components, demands for treatment precision of film thickness or the like are further restricted, and a difference between the film thickness at the central part of the substrate and the film thickness in its peripheral part generated by the conventional sputtering film forming apparatus has become significant. That is, in the conventional sputtering film forming apparatus, the film thickness at the central part of the substrate (wafer) 28 and the film thickness in its peripheral part are not uniform, which causes variations in quality of the electronic components obtained from the same wafer to occur, yields to be lowered, and increase in manufacturing cost.

### SUMMARY OF THE INVENTION

It is an object of this invention to provide a plasma treatment apparatus that can form a film with a uniform thickness in the central part and the peripheral part of a substrate, or uniformly perform plasma treatment on the substrate.

The plasma treatment apparatus according to this invention comprises a plasma generating unit that generates plasma flow; a stage which hold the substrate; and a movement unit which moves the stage in a direction perpendicular to the plasma flow. Furthermore, the substrate is treated by irradiating the plasma flow generated by the plasma generating unit on the substrate.

Other objects and features of this invention will become apparent from the following description with reference to the accompanying drawings.

### BRIEF DESCRIPTION OF THE DRAWINGS

FIG. 1 is a cross-sectional view showing a basic structure of a sputtering film forming apparatus according to an embodiment of this invention;

FIG. 2 is a top view showing movement of a wafer substrate during plasma treatment;

FIG. 3 is a flow chart showing an operating procedure of the sputtering film forming apparatus shown in FIG. 1;

FIG. 4 shows a distribution of the thickness of a thin film formed on the wafer substrate 8 by the sputtering film forming apparatus shown in FIG. 1;

FIG. 5 is a cross-sectional view showing the basic structure of the conventional sputtering film forming apparatus; and

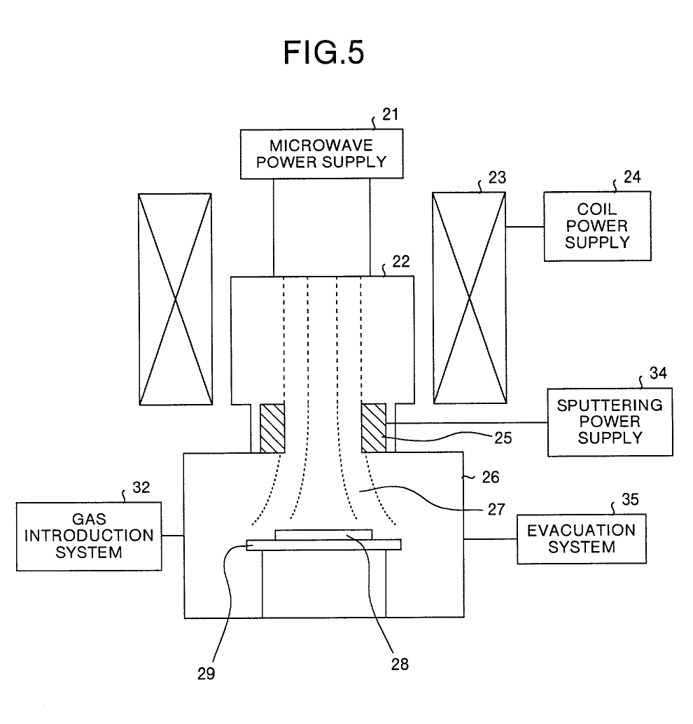

FIG. 6 shows a distribution of the thickness of an aluminum oxide thin film generated by the conventional sputtering film forming apparatus.

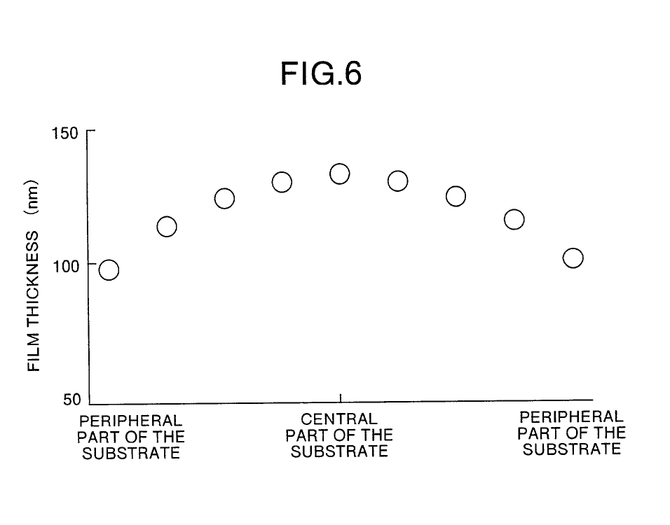

### DESCRIPTION OF THE PREFERRED EMBODIMENTS

Embodiments of the plasma treatment apparatus according to this invention will be explained in detail below with reference to the attached drawings.

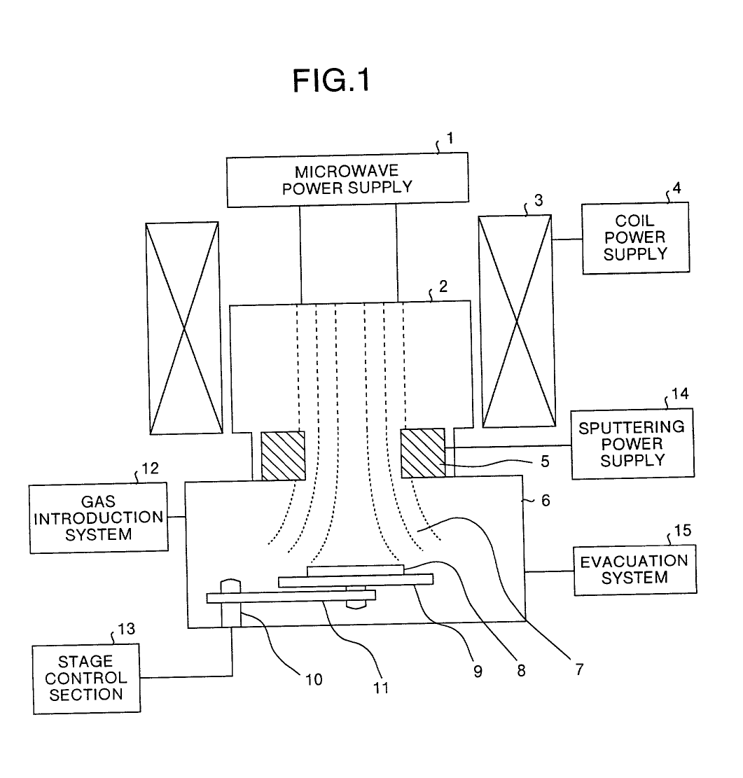

FIG. 1 shows the structure of the sputtering film forming apparatus according to one embodiment of this invention. This sputtering film forming apparatus includes the microwave power supply 1, plasma chamber 2, magnetic coil 3, coil power supply 4, target 5, film forming chamber 6, stage 9, axis 10 for substrate transfer, arm 11, gas introduction system 12, stage control section 13, sputtering power supply 14, and the evacuation system 15.

The plasma chamber 2 is connected to the film forming chamber 6. The microwave power supply 1 is connected to the plasma chamber 2 and supplies microwaves to the plasma chamber 2. The magnetic coil 3 is disposed around the plasma chamber 2. The coil power supply 4 is connected to the magnetic coil 3 and supplies power to the magnetic coil 3.

The evacuation system 15 evacuates the plasma chamber 2 and the film forming chamber 6 to a high vacuum. The gas introduction system 12 introduces gas to the plasma chamber 2 and the film forming chamber 6. The target 5 having a film forming material is disposed at a joint between the plasma chamber 2 and the film forming chamber 6, and is connected to the sputtering power supply 14.

The stage 9 that holds the wafer substrate 8 is connected to the substrate transfer axis 10 through the arm 11. The substrate transfer axis 10 moves the arm 11 under the control of the stage control section 13 to move the stage 9. The stage control section 13 controls loading of the wafer substrate 8 before plasma treatment, unloading of the wafer substrate 8 after the plasma treatment, and movement of the wafer substrate 8 during the plasma treatment.

A film forming procedure by the sputtering film forming apparatus shown in FIG. 1 will be explained below. The plasma chamber 2 and the film forming chamber 6 are evacuated to a high vacuum by the evacuation system 15, and gas is introduced to a desired pressure by the gas introduction system 12. Microwave power is supplied from the microwave power supply 1 to the plasma chamber 2, in which a magnetic field is formed by the magnetic coil 3. The introduced gas is subjected to the electron cyclotron resonance (ECR) in the plasma chamber 2 to form plasma, which becomes a plasma flow 7 flowing from the plasma chamber 2 to the film forming chamber 6.

The sputtering power supply 14 supplies power to the target 5 disposed so as to surround the plasma flow 7, and target particles are scattered through sputtering. The sputtered target particles are deposited on the wafer substrate 8 fixed to the stage 9 to form a thin film. The stage 9 is held vertically with respect to the plasma flow 7. The stage control section 13 moves the stage 9 in a direction perpendicular to the plasma flow 7 through the arm 11 within a range where the wafer substrate 8 contacts the plasma flow 7 during the plasma treatment.

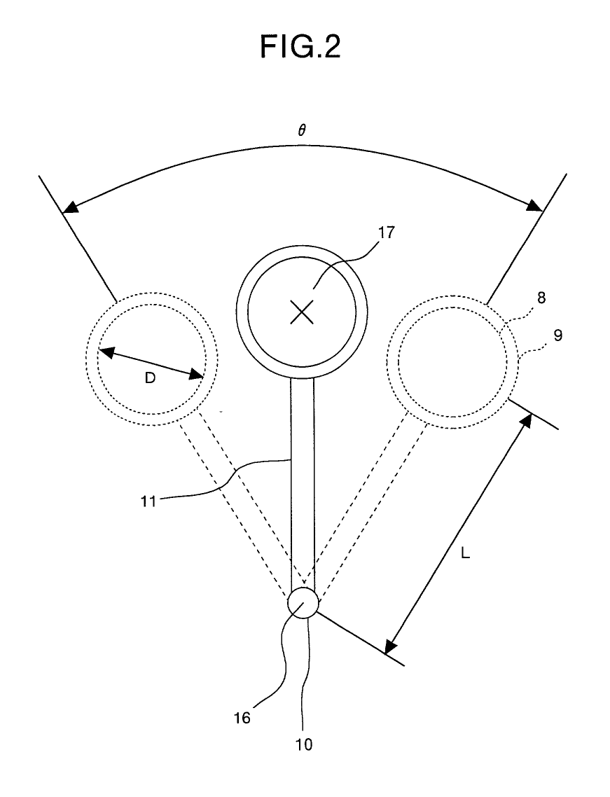

FIG. 2 shows a movement range of the wafer substrate 8 during the plasma treatment. The arm 11 mounted on the substrate transfer axis 10 pivots about a supporting point 16. The wafer substrate 8 is held on the stage 9 fixed to the end of the arm 11. Since the supporting point 16 of the arm is apart from a central position 17 of the plasma flow as a center of the plasma flow 7, the wafer substrate 8 moves within the plasma flow 7 along pivot of the arm.

The arm 11 pivots within the range where the wafer substrate 8 contacts the plasma flow 7. When pivoting by a predetermined angle θ, the arm 11 changes its pivotal direction. Accordingly, the wafer substrate 8 results in repetition of back-and-forth movements within a predetermined range along the circumference of a circle whose radius is L where the length of the arm 11 is L. The range θ in which the arm pivots is set to a value that satisfies the expression as follows:

0<θ≦360×D/(π×L)

where a diameter of the wafer substrate is D.

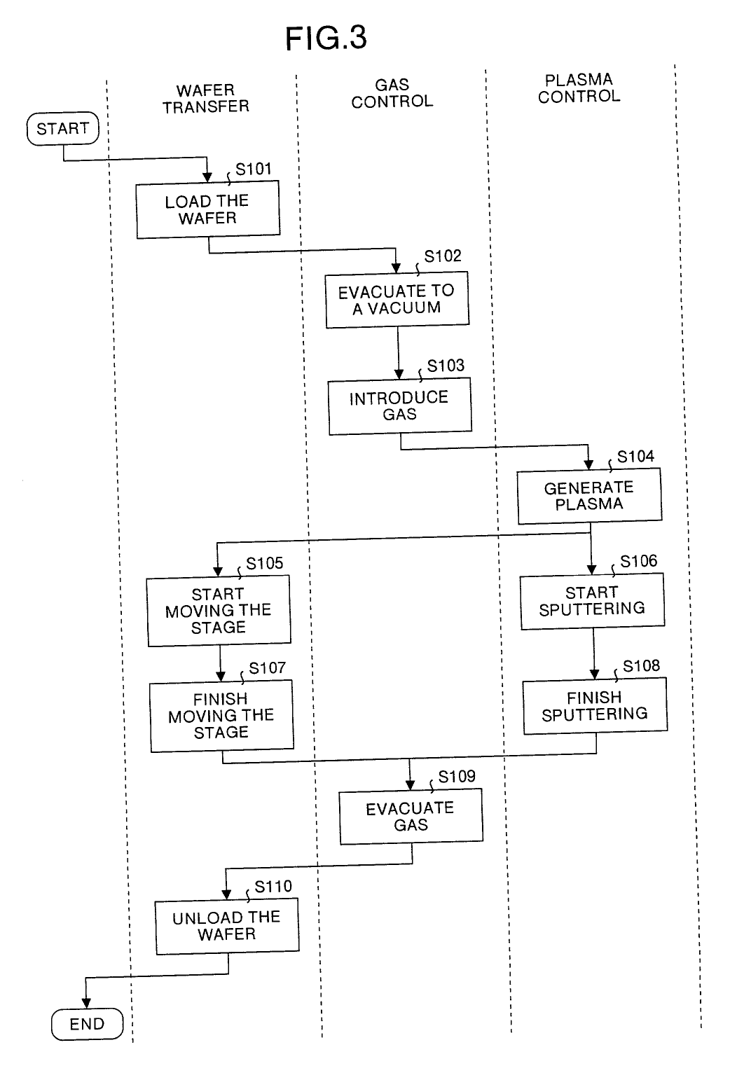

The film forming procedure of the sputtering film forming apparatus shown in FIG. 1 will be explained below with reference to the flow chart shown in FIG. 3. The substrate transfer axis 10 pivots the arm 11 to carry the wafer substrate 8 into the film forming chamber 6 (step S101) The evacuation system 15 evacuates the plasma chamber 2 and the film forming chamber 6 to a high vacuum (step S102). The gas introduction system 12 introduces gas to a desired pressure to the plasma chamber 2 and the film forming chamber 6 (step S103). Microwave power is supplied from the microwave power supply 1 to the plasma chamber 2, in which a magnetic field is formed by the magnetic coil 3 to generate a plasma flow 7 (step S104).

Further, power is supplied to the target 5 to start sputtering target particles (step S106). At the same time, the stage 9 is started to move (step S105). After the predetermined treatment time passes, the sputtering is finished (step S108), and the movement of the stage 9 is finished (step S107).

Subsequently, the gas in the plasma chamber 2 and the film forming chamber 6 is evacuated (step S109). Further, the substrate transfer axis 10 is pivoted to carry out the wafer substrate 8 from the film forming chamber 6 (step S110) and the processing is finished.

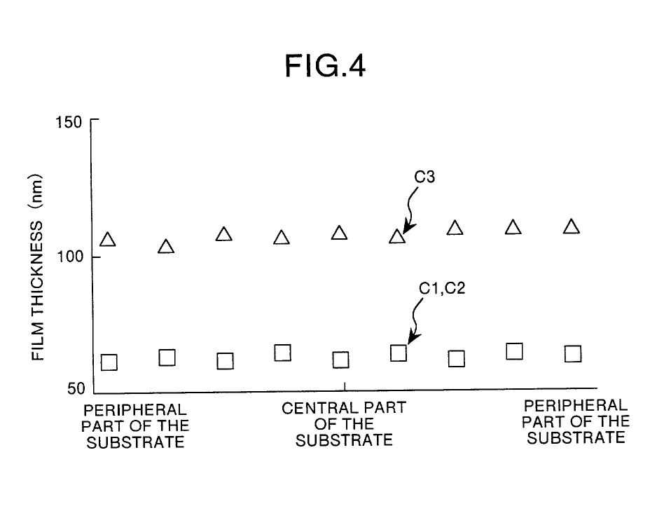

FIG. 4 shows a distribution of the thickness of the film on the wafer substrate 8 formed by the sputtering film forming apparatus shown in FIG. 1. An indium phosphide substrate having a diameter of 50 mm was used as the wafer substrate 8 to form an aluminum oxide thin film. The length of the arm 11 was 250 mm and the pivotal range of the arm 11 was set to 22.9 degrees.

When the arm 11 was pivoted back and forth once (C1) under the conditions that the treatment time was 15.3 minutes and the pivotal velocity of the arm 11 was 3 degrees per minute, the film thickness at the central part of the substrate became about 58 nm, and the film thickness in its peripheral part became about 58 nm.

When the arm 11 was pivoted back and forth twice (C2) under the conditions that the treatment time was 15.3 minutes and the pivotal velocity of the arm 11 was 6 degrees per minute, the film thickness at the central part of the substrate became about 58 nm, and the film thickness in its peripheral part became about 58 nm.

When the arm 11 was pivoted back and forth twice (C3) under the conditions that the treatment time was 30.6 minutes and the pivotal velocity of the arm 11 was 3 degrees per minute, the film thickness at the central part of the substrate became about 100 nm, and the film thickness in its peripheral part became about 100 nm.

In this embodiment, the plasma chamber 2 and the film forming chamber 6 are evacuated to a high vacuum by the evacuation system 15, and gas is introduced to a desired pressure by the gas introduction system 12. Microwave power is supplied from the microwave power supply 1 and a magnetic field is applied by the magnetic coil 3 to generate a plasma flow 7. The target 5 disposed so as to surround the plasma flow 7 is supplied with the power from the sputtering power supply 14 to sputter target particles. The sputtered particles are deposited on the wafer substrate 8 fixed to the stage 9 to form a thin film. The arm 11 moves the stage 9 in a direction perpendicular to the plasma flow 7 within a range where the wafer substrate 8 contacts the plasma flow 7 during the plasma treatment.

In this embodiment, it is possible to enhance uniformity of the film thickness of a thin film formed on the wafer substrate by moving the wafer substrate 8 in a direction perpendicular to the plasma flow 7 during sputtering using plasma.

The movement unit of the wafer substrate 8 functions as a transfer unit for loading and unloading a wafer, which makes it possible to obtain a high-uniformity film forming apparatus with a simple structure, and further enhance uniformity of a film formed by simply improving the existing plasma film forming apparatus.

Although the pivotal velocity of the arm is set to a predetermined value in this embodiment, a specified change may be given to the velocity to move the wafer substrate.

Although it is mentioned above that the wafer substrate is circular, the wafer substrate may have any other shape such a rectangular.

Further, in this embodiment, the wafer substrate 8 is moved within the plasma flow 7 by pivoting the arm 11, but application of this invention is not limited to this method. Therefore, any means can be used if the means can move the stage 9 in a direction perpendicular to the plasma flow 7.

Further, the aluminum oxide thin film is formed on the indium phosphide substrate in this embodiment, but application of this invention is not limited to these materials. Therefore, a thin film of a given material such as silicon oxide, titanium dioxide, amorphous silicon, tangstain oxide, aluminum nitride, or silicon nitride can be formed on a substrate of a given material. Thus, this invention is applicable to a process of forming a film such as a reflection protective film, or a coating film.

Although the sputtering plasma treatment apparatus that forms the thin film on the wafer substrate 8 is explained in this embodiment, application of this invention is not limited to this usage. Therefore, this invention is applicable to a device that performs treatment by using plasma such as etching or milling.

As explained above, according to this invention, the plasma treatment apparatus performs treatment while moving the substrate in a direction perpendicular to the plasma flow during the plasma treatment on the substrate as a target to be treated. Accordingly, it is possible to perform uniform treatment on the central part and peripheral part of the substrate.

Further, the plasma treatment apparatus performs treatment while moving the substrate in a direction perpendicular to the plasma flow within the range to which the plasma flow is irradiated during plasma treatment on the substrate as a target to be treated. Accordingly, it is possible to efficiently perform uniform treatment on the central part and peripheral part of the substrate.

Further, the plasma treatment apparatus pivots the arm connected to the stage to move the substrate loaded on the stage during plasma treatment. Accordingly, it is possible to obtain the plasma treatment apparatus that yields results of uniform treatment with a simple structure by utilizing the arm part, that is used for carry-in and carry-out of the substrate, for movement of the substrate during plasma treatment.

Further, the plasma treatment apparatus has the arm having a length of L, and pivots the arm within the pivotal range θ that satisfies 0<θ≦360×D/(π×L) during plasma treatment on the substrate having a diameter of D. Accordingly, it is possible to minimize the housing of the plasma treatment apparatus that yields results of uniform treatment.

Further, the plasma treatment apparatus performs sputtering to form a thin film on the substrate while sputtering target particles from the target made of the film forming material and moving the substrate in a direction perpendicular to the plasma flow. Accordingly, it is possible to form a thin film having a uniform thickness in the central part and peripheral part of the substrate.

Further, the plasma treatment apparatus performs treatment on the substrate as a target to be treatment using the plasma flow generated by means of electron cyclotron resonance discharge while moving the substrate in a direction perpendicular to the plasma flow. Accordingly, it is possible to perform uniform treatment on the central part and peripheral part of the substrate during the plasma treatment using the electron cyclotron resonance discharge.

Further, the plasma treatment apparatus performs treatment on the substrate as a target to be treatment using the plasma flow generated by means of dc current discharge while moving the substrate in a direction perpendicular to the plasma flow. Accordingly, it is possible to perform uniform treatment on the central part and peripheral part of the substrate during the plasma treatment using the dc current discharge.

Further, the plasma treatment apparatus performs treatment on the substrate as a target to be treatment using the plasma flow generated by means of high frequency discharge while moving the substrate in a direction perpendicular to the plasma flow. Accordingly, it is possible to perform uniform treatment on the central part and peripheral part of the substrate during the plasma treatment using the high frequency discharge.

Further, the plasma treatment apparatus performs etching on the substrate by generating an activated-gas plasma flow while moving the substrate in a direction perpendicular to the plasma flow. Accordingly, it is possible to obtain the plasma treatment apparatus that performs uniform etching on the central part and peripheral part of the substrate.

Further, the plasma treatment apparatus performs milling on the substrate by generating an inactivated-gas plasma flow while moving the substrate in a direction perpendicular to the plasma flow. Accordingly, it is possible to obtain the plasma treatment apparatus that performs uniform milling on the central part and peripheral part of the substrate.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A plasma treatment apparatus comprising:
a plasma generating unit that generates plasma flow;
a stage which hold said substrate; and
a movement unit which moves said stage in a direction perpendicular to the plasma flow,
wherein said substrate is treated by irradiating the plasma flow generated by said plasma generating unit on said substrate.

2. The plasma treatment apparatus according to claim 1, wherein said movement unit can move said stage such that said substrate held by said stage is irradiated with the plasma flow generated by said plasma generating unit.

3. The plasma treatment apparatus according to claim 1, wherein said movement unit comprises:
an arm which supports said stage at one of its ends; and
a pivot unit which is disposed at a position apart from a central position for film formation of the plasma flow and pivots said arm about the other end of said arm as a supporting point.

4. The plasma treatment apparatus according to claim 3, wherein when said substrate is circular is shape, D is the diameter of said substrate and L is the length of said arm, then the pivotal angle range θ of said arm satisfies a relation 0<θ≦360×D/(π×L).

5. The plasma treatment apparatus according to claim 4 further comprising:
a target which is made of a desired material and contacts the plasma flow,
wherein the material of said target is sputtered in the plasma flow, the plasma flow is irradiated onto said substrate thereby forming a film having a composition of the material of said target on said substrate.

6. The plasma treatment apparatus according to claim 5, wherein said plasma generating unit generates the plasma flow using electron cyclotron resonance discharge.

7. The plasma treatment apparatus according to claim 5, wherein said plasma generating unit generates the plasma flow using dc current discharge.

8. The plasma treatment apparatus according to claim 5, wherein said plasma generating unit generates the plasma flow using high frequency discharge.

9. The plasma treatment apparatus according to claim 4, wherein said plasma generating unit generates an activated-gas plasma flow and reacts said activated gas with said substrate to perform etching on said substrate.

10. The plasma treatment apparatus according to claim 4, wherein said plasma generating unit generates plasma flow of an inactivated-gas, irradiates the plasma flow of the inactivated-gas onto said substrate thereby performing milling process on said substrate.

11. The plasma treatment apparatus according to claim 3, wherein when said substrate is not circular is shape, the substrate is moved for a distance from the center of the film formation are which is equal to the length of said substrate in the direction of the movement.
